(19) United States
(12) Patent Application Publication
(10) Pub. No.: US 2005/0133928 A1
(43) Pub. Date: Jun. 23, 2005

(54) Wire loop grid array package

(76) Inventors: Gregory E. Howard, Dallas, TX (US); Howard R. Test, Plano, TX (US); Tz-Cheng Chiu, Plano, TX (US)

Correspondence Address: TEXAS INSTRUMENTS INCORPORATED, P O BOX 655474, M/S 3999, DALLAS, TX, 75265, US

(21) Appl. No.: 10/741,919

(22) Filed: Dec. 19, 2003

(51) Int. Cl. H01L 23/48; H01L 21/44

(52) U.S. Cl. 257/773; 257/780; 257/784; 438/617

(57) ABSTRACT

A device comprising a workpiece (401) with a surface (401a) including a center (402) and an array of bond pads (420), further an array of interconnects (405) of uniform height. Each of these interconnects comprises an elongated wire loop, which has both wire ends (440, 450) attached to one of the bond pads, respectively, and its major diameter (460) approximately normal to the workpiece surface. A substantial number of the loops has an orientation approximately normal to the vector (410) from the workpiece center to the respective bond pad; this number includes more than 30% of the loops located along the workpiece perimeter and more than 10% of the total loops. Examples of workpieces are a semiconductor device, an integrated circuit (IC) chip, and a semiconductor device package.

### FIELD OF THE INVENTION

The present invention is related in general to the field of semiconductor devices and processes and more specifically to the structure and method of interconnection members of integrated circuit chips and packages.

### DESCRIPTION OF THE RELATED ART

During and after assembly of an integrated circuit (IC) chip to an external part such as a substrate or circuit board by solder reflow, and then during device operation, significant temperature differences and temperature cycles appear between the semiconductor chip and the substrate. This is especially true of flip-chip type mounting schemes. The reliability of the solder joint is strongly influenced by the coefficients of thermal expansion of the semiconductor material and the substrate material. For example, there is more than one order of magnitude difference between the coefficients of thermal expansion of silicon and FR-4. This difference causes thermomechanical stresses, most of which are absorbed by the solder joints.

Thermomechanical stress difficulties are aggravated by coplanarity problems of the solder balls and the difficulties involved in obtaining a favorable height-to-diameter ratio and uniformity of the solder interconnection. These difficulties start with the solder ball attach process. As an example, when solder paste is dispensed, the volume of solder paste may vary in volume, making it difficult to control the solder ball height. When prefabricated solder balls are used, the difficulty of avoiding a missed attachment site is well known. A coherent, low-cost method is needed to fabricate interconnection members of uniform configuration and deliver them to the attachment site without missing a site. The method should be flexible enough to be applied for different semiconductor product families and a wide spectrum of design and process variations.

Furthermore, evidence suggests that solder connections of short length and non-uniform width are unfavorable for stress distribution and strain absorption. The stress remains concentrated in the region of the chip-side solder joint, where it may lead to early material fatigue and crack phenomena. Accordingly, solder connections of generally spherical shape are likely to be more sensitive to stress than elongated connections. A new approach is desirable which can produce interconnection members with good stress-absorbing characteristics.

The fabrication methods and reliability problems involving flip-chips re-appear, in somewhat modified form, for ball-grid array type packages, including chip-scale packages (CSP). Most CSP approaches are based on flip-chip assembly with solder bumps or solder balls on the exterior of the package, to interface with system or wiring boards.

Following the solder reflow step, flip-assembled chips and packages often use a polymeric underfill between the chip, or package, and the interposer, substrate, or printed circuit board (PCB). These underfill materials alleviate some of the thermomechanical stress caused by the mismatch of the coefficients of thermal expansion (CTE) of package components. But as a process step, underfilling is time-consuming and expensive, and is preferably avoided.

During the last decade, a number of variations in device structure, materials, or process steps have been implemented in manufacturing in order to alleviate the thermomechanical stress problem. All of them suffer from some drawback in cost, fabrication flow, material selection, and so forth.

A need has therefore arisen for a coherent, low-cost method of assembling flip-chip integrated circuit chips and semiconductor devices that provides a high degree of thermomechanical stress reliability. The method should be flexible enough to be applied for different semiconductor product families and a wide spectrum of design and process variations. Preferably, these innovations should be accomplished using the installed equipment base so that no investment in new manufacturing machines is needed.

### SUMMARY OF THE INVENTION

One embodiment of the invention is a device comprising a workpiece with a surface including a center and an array of bond pads, further an array of interconnects of uniform height. Each of these interconnects comprises an elongated wire loop, which has both wire ends attached to one of the bond pads, respectively, and its major diameter approximately normal to the workpiece surface. A substantial number of the loops has an orientation approximately normal to the vector from the workpiece center to the respective bond pad; this number includes more than 30% of the loops located along the workpiece perimeter and more than 10% of the total loops. Examples of workpieces are a semiconductor device, an integrated circuit (IC) chip, and a semiconductor device package.

Another embodiment of the invention is a device comprising a workpiece with a surface including an array of bond pads, further an array of interconnects of uniform height. Each of these interconnects comprises an elongated wire loop with a major diameter; this diameter is approximately normal to the workpiece surface and has a ratio of loop diameter to wire diameter of 4 to 10. A preferred ratio is 6 to 10, and a more preferred ratio is 6 to 8. Each of the loops has both wire ends attached to one of the bond pads, respectively.

Another embodiment of the invention is a semiconductor assembly comprising an integrated circuit chip with a surface including a center and an array of bond pads, further an array of interconnects of uniform height. Each of these interconnects comprises an elongated wire loop with both wire ends attached to one of the bond pads, respectively, and its major diameter approximately normal to the chip surface. A substantial number of said loops is oriented approximately normal to the vector from the chip center to the respective bond pad; preferably, this number includes more than 30% of the loops located along the chip perimeter and more than 10% of the total loops. The assembly further includes an electrically insulating substrate with a first surface including a first array of contact pads disposed on said first surface, with attachment material disposed on each of the first contact pads. Each of the first contact pads is attached to one of the wire loops, respectively, such that electrical contact between chip and said substrate is established, while a gap is formed between them, which has a width of approximately the major loop diameter. The gap may be filled with encapsulation material such as a molding compound or a non-conductive adhesive.

The substrate of the above assembly may comprise a second surface including a center and a second array of contact pads disposed on this second surface, as well as a plurality of electrically conductive lines connecting the first and second arrays of contact pads. Further, an array of interconnects of uniform height may be attached to the second array of contact pads, wherein each of these interconnects comprises an elongated wire loop with both wire ends attached to one of the second surface contact pads, respectively. The major loop diameter is approximately normal to the second substrate surface; and a substantial number of these loops has an orientation approximately normal to the vector from the second surface center to the respective contact pad. This number includes preferably more than 30% of the loops located along the substrate perimeter and more than 10% of the total loops on the second surface of the substrate.

Another embodiment of the invention is a method for the fabrication of a device by first providing a workpiece with a surface including a center and an array of bondpads. Then, an array of elongated loops is formed by bonding the first wire end to one of the pads, respectively, extending a length of wire while shaping it into a loop, and bonding the second wire end to the same pad, respectively. The loops are formed while controlling the orientation of the loops to maintain normality of the major loop diameter to the surface and normality of the loop opening to the vector from the workpiece center to the respective bond pad, and further controlling the height of the wire loops to maintain uniformity of height, wherein the height is selected to be between 4 and 10 times the diameter of the wire.

Since the workpiece may be a semiconductor chip or a semiconductor package, the embodiments of the invention are related to wire-bonded IC assemblies, semiconductor device packages, surface mount and chip-scale packages. It is a technical advantage that the invention provides a method of assembling high density, high input/output, high speed ICs in packages which may have a need for low profile. These ICs can be found in many device families such as processors, digital and analog devices, wireless and most logic devices, high frequency and high power devices, especially in large chip area categories. Another technical advantage of the invention is it provides the semiconductor devices with great insensitivity to thermo-mechanical stress, and thus high operational device reliability.

The technical advantages represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic perspective view of two individual wire loops formed and attached to a bonding pad according to an embodiment of the invention.

FIG. 2A is a diagram plotting the maximum tensile stress for wire loop compared to baseline solder bump as a function of the wire diameter.

FIG. 2B is a diagram plotting the maximum compressive stress for wire loop compared to baseline solder bump as a function of the wire diameter.

FIG. 3A is a diagram plotting the maximum tensile stress for wire loop compared to baseline solder bump as a function of the loop height.

FIG. 3B is a diagram plotting the maximum compressive stress for wire loop compared to baseline solder bump as a function of the loop height.

FIG. 4 is a schematic perspective view of rows of wire loops in the x- and y-directions, indicating the orientation of the loop opening.

FIG. 5 is a schematic cross section of a portion of a semiconductor chip with wire loops attached to bond pads and soldered to contact pads of a substrate, as another embodiment of the invention.

FIG. 6 is a schematic cross section of a chip-scale semiconductor device as another embodiment of the invention.

FIG. 7 is a schematic cross section of a chip-scale semiconductor device with post as another embodiment of the invention.

### DETAILED DESCRIPTION OF THE PREFERRED EMBODIMENTS

The present invention is related to U.S. Pat. No. 6,268,662, issued on Jul. 31, 2001 (Test et al., “Wire Bonded Flip-Chip Assembly of Semiconductor Devices”).

FIG. 1 depicts schematically a portion of a workpiece 101, which has a surface 102 and a couple of bond pads 103 and 104. Attached to these pads are wire loops 105 and 106, respectively, which are bonded to the respective pad by a ball bonding or wedge bonding technique. In some embodiments, workpiece 101 is a semiconductor chip made of silicon, silicon germanium, gallium arsenide, or another semiconductor compound. In this case, the chip may contain an integrated circuit (IC) with bond pads 103 and 104. The pads are typically made of metal having a top surface of aluminum, aluminum alloy, gold, palladium, or other bondable metal or alloy. In a semiconductor chip, the surface 102 is usually covered by an insulating, protective overcoat, for instance moisture-impermeable silicon nitride.

In other embodiments, workpiece 101 is semiconductor package made of ceramic or molding compound (usually an epoxy-based polymerized plastic). In that case, the pads 103 and 104 are contact pads, typically made of copper, with a bondable surface, preferably containing nickel, gold, palladium, or alloys thereof. In a ceramic or plastic package, surface 102 is non-conductive.

As FIG. 1 shows, an individual bond pad or contact pad such as 103 or 104 is preferably shaped as a rectangle or a square. However, in some embodiments, other pad geometries are being employed, such as circles or angled pads. A typical side length of a pad like 103 is between about 40 to 150 μm, preferably between 90 and 100 μm. It is easy for most pad configurations to determine the center of the pad. As an example, in pad 104 of FIG. 1, the crossing point of diagonals 110 and 111 determines the pad center 112.

The pitch 120 between neighboring bond pads of semiconductor chips is typically in the range from 50 to 200 μm, for chips with ICs of numbers of high input/output (I/O) terminals, pitch 120 is preferably between 50 and 75μ. In many embodiments, a plurality of pads form an array. An array may have the pads arranged in rows with regular pad pitch, often around the chip perimeter and frequently in parallel rows, or the pads may have an arbitrary distribution. For most ICs of low and high I/O count, the bond pads are distributed around the chip perimeter in order to simplify the wire bonding process steps.

FIG. 1 shows one interconnection attached to each bond pad. The interconnection consists of a loop formed by a length of bonding wire, loop 105 for pad 103 and loop 106 for pad 104. In FIG. 1, each loop uses a bonding wire of a selected diameter 130, and has on one end a ball bond 140 and on the other end a stitch bond 150. Other embodiments may employ two wedge bonds. The bonding wire is preferably round; the wire diameter 130 is typically between 10 and 30 μm, and preferably between 15 and 25 μm.

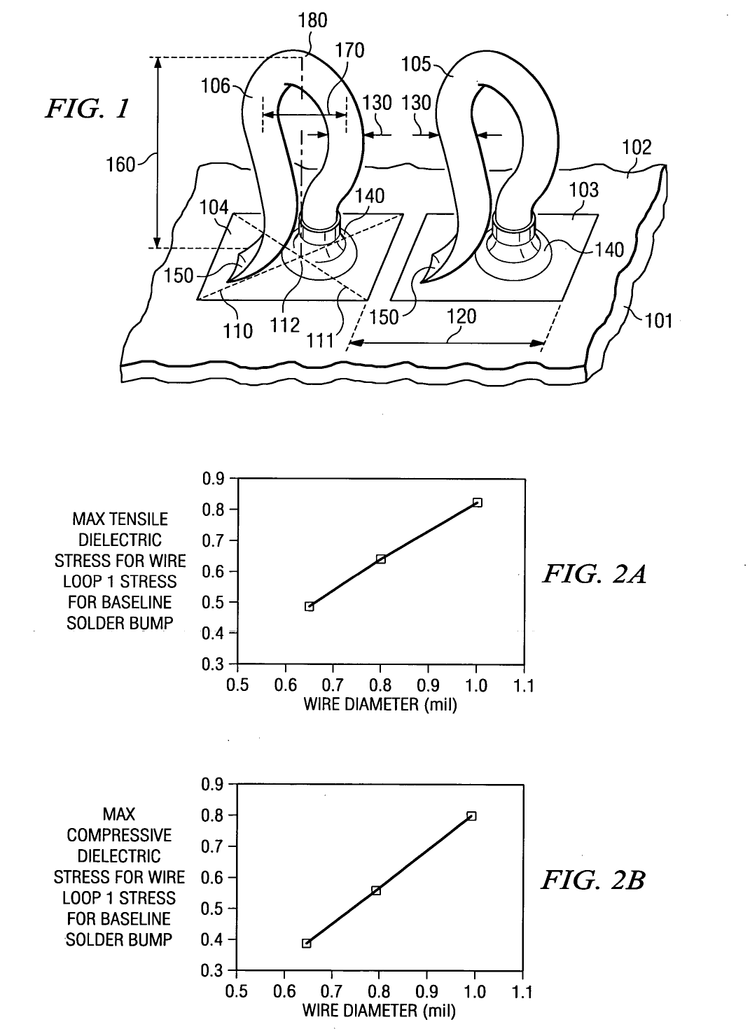

Considering the stress-absorbing capability of loops made different wire diameters, stress modeling as well as experimental data show that tensile and compressive stresses in the dielectric under the bond pad are reduced with decreasing wire diameter. As an example, FIGS. 2A and 2B show modeling results of stress reduction compared to baseline solder ball interconnections, when a loop height of 45 μm is chosen as reference height for the loops. As the graphs indicate, the stresses decrease about linearly with shrinking wire diameter so that a loop made of a 15 μm (0.65 mil) diameter gold wire decreases the stresses to approximately 50% of the values observed for loops made of 25 μm (1.0 mil) diameter wire.

The wire may consist of gold or gold with optional very small contents of beryllium, copper, palladium, iron, silver, calcium, or magnesium. These alloyed elements are sometimes employed to control the heat-affected zone in ball formation (which would be mechanically weak for bending or other deformation stresses) and for enhancing the elasticity of the wire. A preferred gold alloy adds about 1% palladium to the gold. Other selections for wire materials include copper and copper alloys, and aluminum and aluminum alloys. The wire material has to be wettable by solder and other reflowable metals, solder paste, or conductive or non-conductive adhesives, with or without the use of flux.

The wire bonding process for gold wires begins by positioning the semiconductor chip on a heated pedestal to raise the temperature to between 150 and 300° C. The wire is strung through a capillary. At the tip of the wire, a free air ball is created using either a flame or a spark technique. The ball has a typical diameter from about 1.2 to 1.6 wire diameters. The capillary is moved towards the chip bonding pad (103 or 104 in FIG. 1) and the ball is pressed against the metallization of the pad. For pads of aluminum, a combination of compression force and ultrasonic energy creates the formation of gold-aluminum intermetallics and thus a strong metallurgical bond. The compression (also called Z- or mash) force is typically between about 17 and 75 g; the ultrasonic time between about 10 and 20 ms; the ultrasonic power between about 20 and 50 mW. At time of bonding, the temperature usually ranges from 150 to 270° C. In the case of copper wire on copper pad, only metal interdiffusion takes place in order to generate the strong weld.

Alternatively, both wire ends can be wedge bonded to the same bonding pad.

Computerized wire bonders are commercially available (for instance from Kulicke & Soffa, U.S.A., and Shinkawa, Japan) which allow the formation of small yet reliable ball contacts and tightly controlled shape of the wire loop. The technical advances of the bonders further allow the selection of major and minor loop diameters, the orientation of the loop opening, the detail of the loop shape, and the reproducibility of the loops within very tight tolerances.

Finally, the capillary reaches its desired destination; for the present invention, this is the same bonding pad from which the bonding operation originally started (in FIG. 1, pads 103 or 104). The capillary is lowered to touch the pad; with the imprint of the capillary, a metallurgical stitch bond is formed, and the wire is broken off to release the capillary. Stitch contacts are small yet reliable; the lateral dimension of the stitch imprint is about 1.5 to 3 times the wire diameter (its exact shape depends on the shape of the capillary used, such as capillary wall thickness and capillary footprint). Consequently, the area of bonding pads 103 and 104 in FIG. 1 can be designed small yet so that both the ball and the stitch of the wire bond can be placed on it without affecting the surrounding border of the protective overcoat of surface 102.

An example of the wire loop formed by the capillary under computer control is shown in FIG. 1. The loop has a major diameter, or height, 160 and a minor diameter 170. The loop height is selected so that it contributes to optimize the stress-absorbing characteristic of the loop. Experimental data and modeling results indicate that tensile and compressive stresses in the dielectric under the bond pad are reduced with increasing loop height.

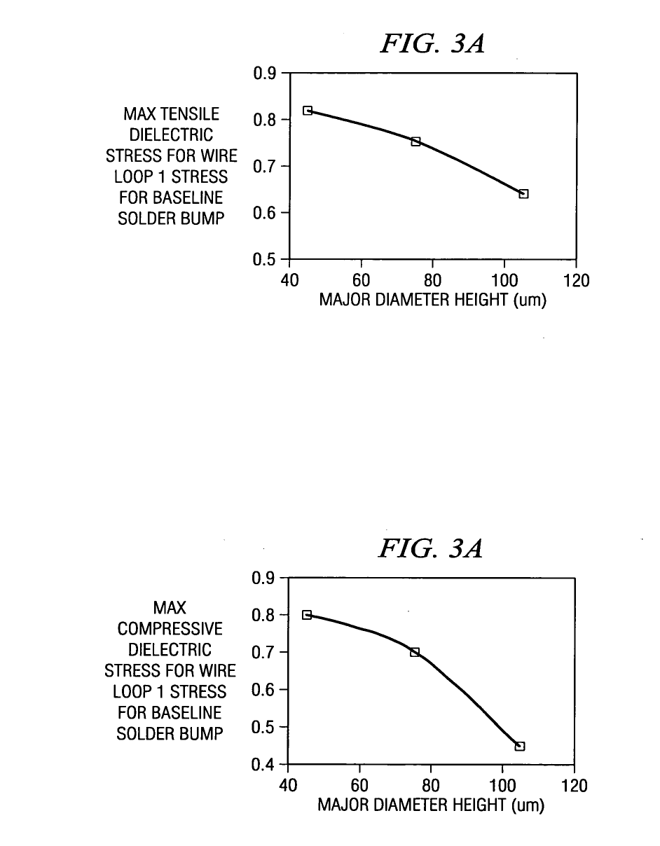

As an example, FIGS. 3A and 3B show modeling results of stress reduction compared to baseline solder ball interconnections, when gold wire loops of 25 μm diameter are employed. For loop heights more than 100 μm (four times the wire diameter), the tensile stress (FIG. 3A) is reduced to less than 65% of the baseline value, and the compressive stress (FIG. 3B) is reduced to less than 50% of the baseline value.

Loops have by nature a certain height and are formed by a wire of a certain diameter. Combining these parameters of height and diameter, ranges of desired stress reduction can be expressed by the ratio of the major loop diameter (loop height) to the wire diameter. Within the practical limits of semiconductor device technology, the desirable ratio of loop height to wire diameter is between about 4 and 10, more preferably between 6 and 10, and still more preferably between 6 and 8. Narrow loops with a shape more elongated than a circle are preferred, with the minor loop diameter (170 in FIG. 1) preferably in the range of 2 to 4 wire diameters.

For many silicon ICs, embodiments of the major loop diameter (160 in FIG. 1) are in the range from about 50 to 250 μm, with a preferred height of about 90 to 110 μm. The height has to be controlled to within ±2 to 4 μm. The same limiting tolerance applies to the height of all loops in an array of wire loops. As defined herein, an array of wire loops is called of uniform height, when the height of each wire loop exhibits this tolerance.

It is an advantage of the present invention that the bond pad pitch 120 can be maintained at a fine pitch, since the major loop diameter 160 can be controlled without pitch change. Also, the ratio between major and minor diameters can be modified in order to achieve fine pitch of the bonding pads.

When chips with this range of major and minor diameters are attached to substrates, the wire loops will exhibit sufficient elasticity to act as stress-absorbing springs. The loops have a geometry designed to accommodate bending and stretching far beyond the limit which simple elongation of the wire material would allow, based on the inherent wire material characteristics. Consequently, the greater contribution to the stress-absorbing capability of the loops derives from geometrical flexibility and the smaller contribution from material characteristics.

The preferred orientation of the major diameter is substantially perpendicular to the plane 102 of the bonding pad, or contact pad. In embodiments, in which the workpiece 101 is a semiconductor chip, plane 102 is the plane of the active surface of the chip containing the IC. In addition, any offset of the loop apex 180 versus the bonding pad center 112 (connected by dash-dotted line in FIG. 1) needs to be constant in direction as well as magnitude from loop to loop (in order to enable alignment with the substrate contact pads during assembly). In FIG. 1, this offset is zero.

Publications in the technical literature have found for semiconductor devices that tensile, compressive and shear stresses across semiconductor chips are not equally distributed, but increase from the chip center towards the chip periphery, and especially strong towards the chip corners. See, for instance, “Computer-Aided Stress Modeling for Optimizing Plastic Package Reliability” by S. Groothuis, W. Schroen, and M. Murtuza, 23rd Ann. Proc. IEEE Reliability Physics, 1985, pp. 184-191. The stress gradients are oriented towards the chip center and particularly steep in the chip corners.

In order to counteract the stress gradient, it is most effective to orient the opening of the loop (the plane of the loop opening) normal to the stress gradient. Since the stress gradients are directed towards the center of the workpiece (for instance the chip), the vector form the workpiece center towards the (center of the) bond pad is in the same direction. Consequently, an equivalent statement is that as an effective stress countermeasure, the loop openings should be oriented normal to the vector from the workpiece center to the center of the respective bond pad.

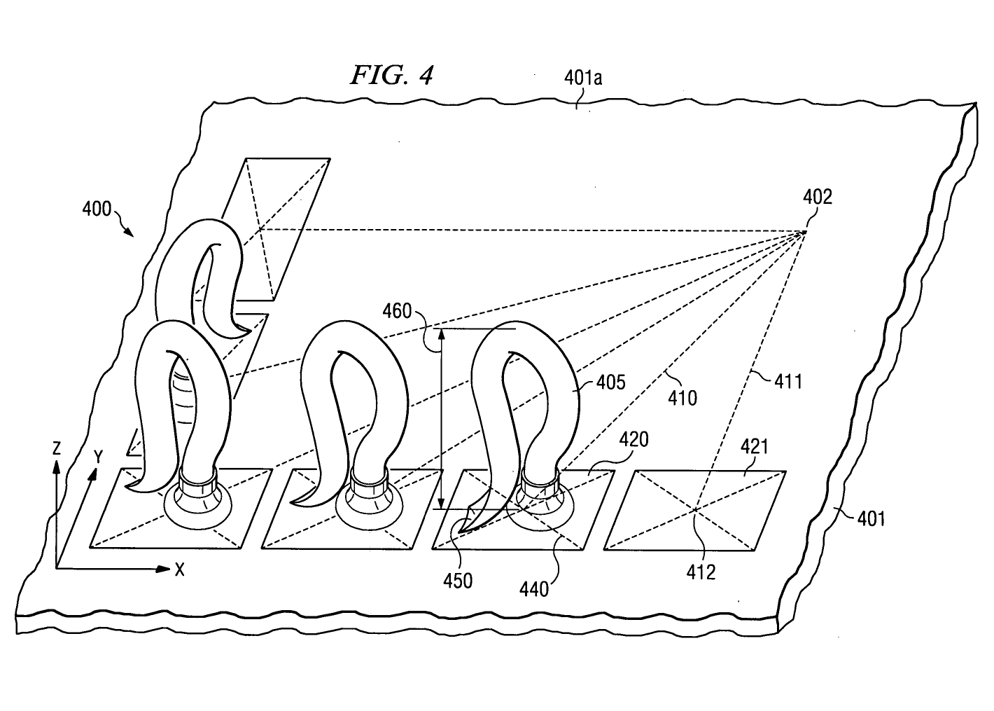

For a device generally designated 400, FIG. 4 illustrates the orientation of an array of loops 405 relative to the center 402 of a workpiece 401. The loops 405 are bonded to pads 420 on the surface 401a of workpiece 401. For a substantial number of loops, the loop opening is approximately normal to the vector 410 from workpiece center 402 to the respective bond pad 420 of loop 405. As defined herein, a substantial number includes more than 30% of the loops along the workpiece perimeter, and more than 10% of the total number of loops attached to the workpiece. The vector from center 402 is directed towards the center of the bond pad; for instance, vector 411 from center 402 is directed towards center 412 of bond pad 421.

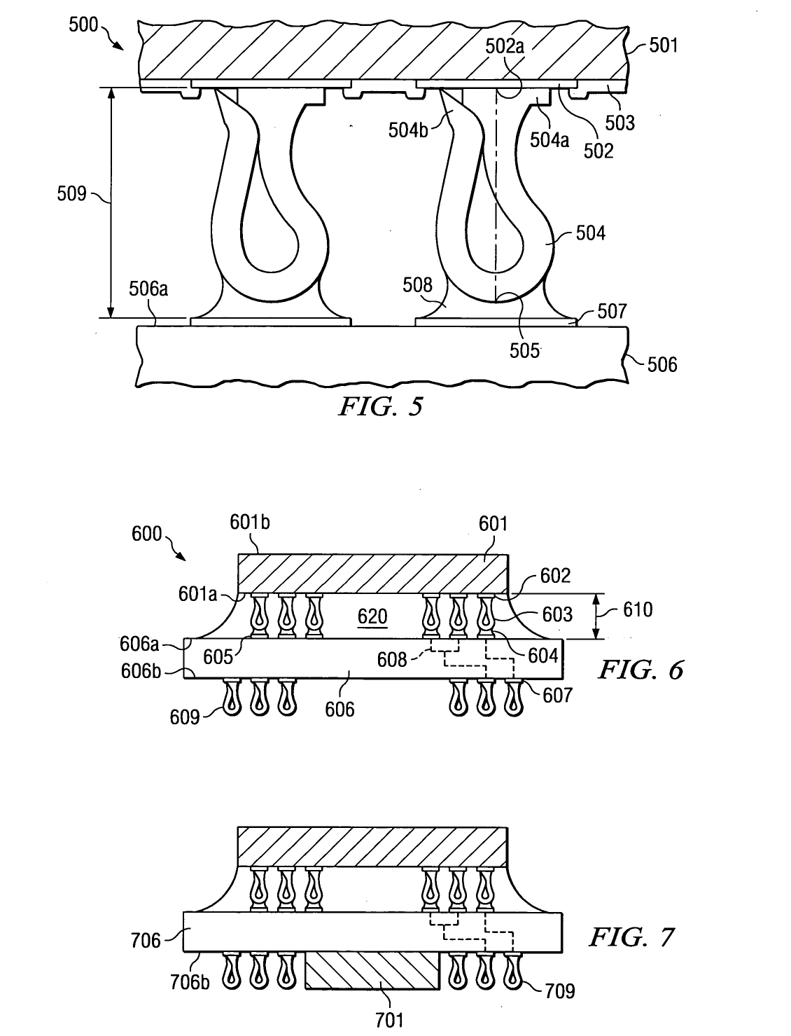

FIG. 5 illustrates an assembly, generally designated 500, of a chip to a substrate as another embodiment of the present invention. FIG. 5 is a simplified and schematic cross section through a portion of chip 501 comprising bond pads 502 and surrounding protective overcoat 503. Wire loops 504 are bonded to the bond pads 502, each loop with one ball 504a and one respective stitch 504b of the wire welded to the bond pad metallization. The loops have a major and a minor diameter, as explained in FIG. 1, with the major diameters defining the height of the loops, which fall within the tight tolerance discussed in conjunction with FIG. 1 so that the loops of the array exhibit uniform height.

Furthermore, the major diameter of all loops is substantially perpendicular to the plane of the active chip surface. The center 502a of the bonding pad and the apex 505 of the loop have an offset of zero in FIG. 5 (they can be connected by the perpendicular dashed line); if in a device, however, that offset is non-zero, it must be constant in direction and magnitude from loop to loop in order to enable satisfactory alignment between the loops and the respective contact pads on the substrate.

In FIG. 5, chip 501 is attached to a substrate 506 made of insulating material and having a plurality of contact pads 507 disposed on its first surface 506a. Usually, the contact pads consist of copper with a flash of gold for reliable bondability. However, if metal interdiffusion with the solder paste or other attach material is to be kept at a minimum, a thin layer of refractory metal (titanium or titanium-tungsten alloy, 40 to 700 nm thick, preferred 50 nm) may be deposited over the copper layer, followed by a layer of platinum or platinum-rich alloy (200 to 800 nm thick, preferred 500 nm). On its second surface (not shown in FIG. 5, but in related FIGS. 6 and 7) is disposed a similar plurality of contact pads. Contact pads 507 serve as attachment places for attachment material 508, typically tin, indium, or any of the numerous tin alloys, solder pastes, and conductive (for instance, silver-filled) adhesives.

The attachment material should wet the wires, but should enable reliable attachment with or without the need of flux. The attachment material may fill the opening of the loops partially without impeding the spring-like elasticity of the loops. For some embodiments it is preferred to select the attachment materials, especially solders, so that they are compatible with multiple reflow. This feature also facilitates rework.

Substrate 506 is made of insulating (polymer or ceramic) material and may be selected from a group consisting of FR-4, FR-5 and BT resin. Integral with the substrate is a plurality of electrically conductive routing strips. FR-4 is an epoxy resin, or a cyanate ester resin, reinforced with a woven glass cloth. It is available from Motorola Inc., USA, or from Shinko Corp., Japan. or from Ibiden Corp., Japan. FR-5 and BT resin are available from the same commercial sources. When selecting the material for the substrate, four parameters should be considered, namely the coefficient of thermal expansion (CTE), glass transition temperature, thickness, and dielectric constant.

The CTE for FR-4 is about 16 ppm/° C.; CTE for silicon is about 2 ppm/° C. This difference in CTE between substrate 506 in FIG. 5 made from FR-4 and the silicon chip 501 causes thermo-mechanical stresses in temperature variations during assembly steps or device operation and may lead to failure of devices when conventional solder bumps or balls are used. It is a major advantage of the embodiments (FIGS. 5, 6, and 7) of the present invention that the wire loops are tolerant of thermomechanical stresses so that CTE differences as cited above can be accepted.

The stand-off height 509 in FIG. 5 is defined as the distance between the surfaces of the chip bonding pads 502 and the substrate contact pads 507. It is a technical advantage for the embodiments of the present invention that this design parameter can be varied over a wide range, since it offers the device designers flexibility with regard to the overall thickness of the product. Preferred standoff heights range from about 50 to 150 μm.

FIG. 6 shows schematically another embodiment of the present invention, a chip-scale semiconductor device generally designated 600, which features the application of the wire loop concept at two stages of device fabrication. An individual chip 601 has a first, or active, surface 601a and a second, or passive, surface 601b; the active surface includes the IC and a plurality of bond pads 602. Bonded to each bond pad is a wire loop 603, with its major diameter substantially perpendicular to the active chip surface 601a. Together, these loops form an array of uniform height. The loops are oriented normal to the vector form the chip center (not shown in FIG. 6) to the respective bond pads, and have constant offsets in both direction and magnitude of their apex relative to their bonding pad centers, as described in detail in FIGS. 1 and 4.

Each loop 603 is attached using attachment or solder material 604 to a contact pad 605 disposed on the first surface 606a of electrically insulating substrate 606. In the embodiment of FIG. 6, substrate 606 has approximately the size of chip 601 to create a chip-size device. In other embodiments, the size of substrate 606 is larger than the individual chip 601 in order to accommodate the assembly of a plurality of chips on one substrate. Contact pads 605 are connected by a plurality of electrically conductive routing strips 608, integral with substrate 606, to a plurality of contact pads 607 disposed on the second surface 606b of substrate 606.

In the first step of the attachment process of chip 601 to substrate 606, chip 601 with the wire loops 603 and substrate 606 with the attachment material 604 are aligned such that each wire loop 603 is aligned with one contact pad 605 of substrate 606. Next, actual contact is established between the wire bonds of the chips and the substrate contact pads with the attachment material. In the following step, enough energy is applied to the substrate to let the attachment material reach liquid state and induce wetting of portions of the loops. If solder is used, this means melting and reflowing the solder. If conductive adhesive is used, this means active adhesion to portions of the loops. After wetting and forming reliable contact meniscus, the heating energy is removed, the attachment material cools and hardens, forming physical bonds between the substrate contact pads and the chip wire loops. Consequently, the chips are attached to the substrate while a gap 610 is formed between the chip and the substrate. Gap 610 has approximately the width of the major diameter of loops 603. More precisely, the gap has a width of the standoff height (509 in FIG. 5) plus the thickness of the substrate metallization (605 in FIG. 6).

In some embodiments of device 600 shown in FIG. 6, gap 610 is filled with an underfiller material 620, for example an epoxy-based polymer. In other embodiments of device 600, not shown in FIG. 6, transfer molding is used to create the underfilling together with an encapsulation by an epoxy-based molding compound having fillers of silica and anhydrides. In the molding process, all wire loops 603, the active chip surface 601a and the substrate first surface 606a are completely covered and protected.

To each of the substrate contact pads 607 is a wire loop 609 attached so that this array of loops 609 enables mechanical and electrical connection of device 600 to external parts such as motherboards.

FIG. 7 illustrates another embodiment of the invention especially suitable for high power devices. A metal post 701 is attached to the second surface 706b of substrate 706. It has the same height as the wire loops 709 attached to the second substrate surface 706b. It thus acts as a stand-off control in board assembly, but also improves the heat conduction form the device substrate to the external part, for instance the motherboard.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A device comprising:
a workpiece having a surface including a center and an array of bond pads;
an array of interconnects of uniform height, each of said interconnects comprising an elongated wire loop having both wire ends attached to one of said bond pads, respectively, and its major diameter approximately normal to said surface; and
a substantial number of said loops having an orientation approximately normal to the vector from said center to said respective bond pad.

2. The device according to claim 1 wherein said substantial number includes more than 30% of the loops located along the workpiece perimeter and more than 10% of the total loops.

3. The device according to claim 1 wherein said device is a semiconductor device.

4. The device according to claim 1 wherein said workpiece is an integrated circuit chip having a surface including a center and an array of bond pads.

5. The device according to claim 1 wherein said workpiece is a semiconductor device package having a surface including a center and an array of bond pads.

6. A device comprising:
a workpiece having a surface including an array of bond pads; and
an array of interconnects of uniform height, each of said interconnects comprising an elongated wire loop having a major diameter, said diameter approximately normal to said surface and having a ratio of loop diameter to wire diameter of 4 to 10, each of said loops having both wire ends attached to one of said bond pads, respectively.

7. The device according to claim 6 wherein said ratio is 6 to 10.

8. The device according to claim 6 wherein said ratio is 6 to 8.

9. The device according to claim 6 wherein said wire loops further having constant offsets in both direction and magnitude of their apex relative to their bond pad centers.

10. The device according to claim 6 wherein said device is a semiconductor device.

11. The device according to claim 6 wherein said workpiece is an integrated circuit chip having an array of bond pads.

12. The device according to claim 6 wherein said workpiece is a semiconductor device package having an array of contact pads.

13. A semiconductor assembly comprising:
an integrated circuit chip having a surface including a center and an array of bond pads;
an array of interconnects of uniform height, each of said interconnects comprising an elongated wire loop having both wire ends attached to one of said bond pads, respectively, and its major diameter approximately normal to said surface, and a substantial number of said loops oriented approximately normal to the vector from said center to said respective bond pad;
an electrically insulating substrate having a first surface including a first array of contact pads disposed on said first surface, with attachment material disposed on each of said first contact pads;
each of said first contact pads being attached to one of said wire loops, respectively, such that electrical contact between said chip and said substrate is established, while forming a gap therebetween having a width of approximately said major loop diameter.

14. The assembly according to claim 13 wherein said substantial number includes more than 30% of the loops located along the chip perimeter and more than 10% of the total loops.

15. The assembly according to claim 13 further comprising encapsulation material within said gap.

16. The assembly according to claim 15 wherein said encapsulation material is a molding compound.

17. The assembly according to claim 15 wherein said encapsulation material is a polymeric, non-conductive adhesive, which shrinks volumetrically after polymerization, exerting compressive stress.

18. The assembly according to claim 13 wherein said attachment material is selected from a group consisting of tin, tin alloys, solder paste, and conductive adhesive.

19. The assembly according to claim 13 wherein said electrically insulating substrate further comprises a second surface including a center and a second array of contact pads disposed on said second surface, and a plurality of electrically conductive lines connecting said first and second arrays of contact pads.

20. The assembly according to claim 19 further comprising an array of interconnects of uniform height attached to said second array of contact pads, each of said interconnects comprising:
an elongated wire loop having both wire ends attached to one of said contact pads, respectively;
the major loop diameter approximately normal to said second substrate surface; and
a substantial number of said loops having an orientation approximately normal to the vector from said second surface center to said respective contact pad.

21. A semiconductor assembly comprising:
an integrated circuit chip having a surface including a center and an array of bond pads;
an array of interconnects of uniform height, each of said interconnects comprising an elongated wire loop having a major diameter, said diameter approximately normal to said surface and having a ratio of loop diameter to wire diameter of 4 to 10, each of said loops having both wire ends attached to one of said bond pads, respectively;
an electrically insulating substrate having a first surface including a first array of contact pads disposed on said first surface, with attachment material disposed on each of said first contact pads;
each of said first contact pads being attached to one of said wire loops, respectively, such that electrical contact between said chip and said substrate is established, while forming a gap therebetween having a width of approximately said major loop diameter.

22. The assembly according to claim 21 further comprising encapsulation material within said gap.

23. The assembly according to claim 21 wherein said electrically insulating substrate further comprises a second surface including a center and a second array of contact pads disposed on said second surface, and a plurality of electrically conductive lines connecting said first and second arrays of contact pads.

24. The assembly according to claim 23 further comprising an array of interconnects of uniform height attached to said second array of contact pads, each of said interconnects comprising:
an elongated wire loop having both wire ends attached to one of said contact pads, respectively;
the major loop diameter approximately normal to said second substrate surface; and
said major diameter having a ratio of loop diameter to wire diameter of 4 to 10.

25. A method for the fabrication of a device comprising the steps of:
providing a workpiece having a surface including a center and an array of bond pads;
forming an array of elongated loops by bonding the first wire end to one of said pads, respectively, extending a length of wire while shaping it into a loop, and bonding the second wire end to the same pad, respectively;
controlling the orientation of said loops to maintain normality of the major loop diameter to said surface;
controlling the orientation of said loops to maintain normality of the loop opening to the vector from said workpiece center to said respective bond pad;
controlling the height of said wire loop to be between 4 and 10 times the diameter of said wire; and
controlling the height of said loops to maintain uniformity of said height.

26. The method according to claim 25 further comprising the step of controlling the offsets of the apex of said loops relative to their bond pad centers to maintain constancy of direction as well as magnitude.

27. A method for the fabrication of a semiconductor assembly comprising the steps of:
providing an integrated circuit chip having a surface including a center and an array of bond pads;
forming an array of elongated loops by bonding the first wire end to one of said pads, respectively, extending a length of wire while shaping it into a loop, and bonding the second wire end to the same pad, respectively;
controlling the orientation of said loops to maintain normality of the major loop diameter to said surface;
controlling the orientation of said loops to maintain normality of the loop opening to the vector from said center to said respective bond pad;
controlling the height of said wire loop to be between 4 and 10 times the diameter of said wire;
controlling the height of said loops to maintain uniformity of said height;
providing an electrically insulating substrate having a first surface including a first array of contact pads disposed on said first surface, an second surface including a center and a second array of contact pads disposed on said second surface, and a plurality of electrically conductive lines connecting said first and second arrays of contact pads;
disposing attachment material on each of said first contact pads;
attaching one of said chip wire loops to each of said first contact pads, respectively, such that electrical contact between said chip and said substrate is established, while forming a gap therebetween having a width of approximately said major loop diameter.

28. The method according to claim 27 further comprising the step of filling said gap with encapsulation material.

29. The method according to claim 27 further comprising the steps of:
forming an array of elongated loops on said second surface of said substrate by bonding the first wire end to one of said second contact pads, respectively, extending a length of wire while shaping it into a loop, and bonding the second wire end to the same pad, respectively;
controlling the orientation of said loops to maintain normality of the major loop diameter to said second substrate surface;
controlling the orientation of said loops to maintain normality of the loop opening to the vector from said second surface center to said respective contact pad;
controlling the height of said wire loop to be 4 and 10 times the diameter of said wire; and
controlling the height of said loops to maintain uniformity of said height.
